(19) United States
(12) Patent Application Publication
(10) Pub. No.: US 2026/0066890 A1
(43) Pub. Date: Mar. 5, 2026

(54) COMMUNICATION DEVICE

(71) Applicant: Infineon Technologies Austria AG, Villach (AT)

(72) Inventors: Karl Egil NORLING, Villach (AT); Mihai-Alexandru IONESCU, Grafing bei München (DE); Marco PARENZAN RUPENA, Villach (AT); Simone FABBRO, Udine (IT); Lucrezia NAVARIN, Vigonovo (IT); Andrea BEVILACQUA, Padova (IT)

(21) Appl. No.: 19/316,677

(22) Filed: Sep. 2, 2025

(30) Foreign Application Priority Data
Sep. 2, 2024 (DE) 102024208321.6

(51) Int. Cl. H03K 17/0412; H04B 1/04; H04B 1/16; H04B 1/18

(52) U.S. Cl. CPC H03K 17/04123; H04B 1/0475; H04B 1/1638; H04B 1/18

(57) ABSTRACT

According to some embodiments, a communication device includes a signal generator configured to generate a carrier signal, control logic configured to encode first data in the carrier signal, a barrier device including an isolation barrier connected to the signal generator and a tuning circuit connected to the isolation barrier to establish a resonance condition for communicating the carrier signal over the isolation barrier, and a receiver configured to decode second data from a remote device based on at least one parameter of the carrier signal.

### TECHNICAL FIELD

The present disclosure relates generally to electronic circuits, and, more particularly, to an isolated communication device.

### BACKGROUND

Digital isolators, solid state relays and isolators, isolated sensors, analog-to-digital converters, digital-to-analog converters, or other isolated devices are example electronic applications that may combine an electric isolation barrier with data transmission across the isolation barrier. Galvanically isolated gate drivers use a signaling technique across an isolation barrier to communicate primary channel data. Primary channel data may include a pulse width modulation (PWM) control signal from a controller that is transmitted to an output chip that drives a switch, such as a power transistor.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

According to some embodiments, a communication device comprises a signal generator configured to generate a carrier signal, control logic configured to encode first data in the carrier signal, a barrier device comprising an isolation barrier connected to the signal generator and a tuning circuit connected to the isolation barrier to establish a resonance condition for communicating the carrier signal over the isolation barrier, and a receiver configured to decode second data from a remote device based on at least one parameter of the carrier signal.

According to some embodiments, a gate driver comprises an on-off keying receiver configured to decode first data from a carrier signal, a device configured to modify at least one parameter of the carrier signal, and control logic configured to control the device to encode second data.

According to some embodiments, a method comprises generating a carrier signal encoded with first data, communicating the carrier signal over a barrier device, the barrier device comprising an isolation barrier and a tuning circuit connected to the isolation barrier to establish a resonance condition for communicating the carrier signal over the isolation barrier, and decoding second data from a remote device based on at least one parameter of the carrier signal.

According to some embodiments, a device comprises means for generating a carrier signal encoded with first data, means for communicating the carrier signal over a barrier device, the barrier device comprising an isolation barrier and a tuning circuit connected to the isolation barrier to establish a resonance condition for communicating the carrier signal over the isolation barrier, and means for decoding second data from a remote device based on at least one parameter of the carrier signal.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### BRIEF DESCRIPTION OF THE DRAWINGS

FIG. 1 is a schematic diagram of a communication device, according to some embodiments.

FIGS. 2A, 2B, and 2C are diagrams of isolation circuits, according to some embodiments.

FIG. 3 is a diagram of a detector, according to some embodiments.

FIG. 4 is a diagram of a modulated carrier waveform, according to some embodiments.

FIG. 5 is a diagram of a receiver, according to some embodiments.

FIGS. 6-8 are diagrams of modulated carrier waveforms used for communication, according to some embodiments.

FIG. 9 illustrates a method of communicating data, in accordance with some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

Equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually exchangeable.

In this regard, directional terminology, such as “top”, “bottom”, “below”, “above”, “front”, “behind”, “back”, “leading”, “trailing”, etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope defined by the claims. The following detailed description, therefore, is not to be taken in a limiting sense.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In embodiments described herein or shown in the drawings, any direct electrical connection or coupling, i.e., any connection or coupling without additional intervening elements, may also be implemented by an indirect connection or coupling, i.e., a connection or coupling with one or more additional intervening elements, or vice versa, as long as the general purpose of the connection or coupling, for example, to transmit a certain kind of signal or to transmit a certain kind of information, is essentially maintained. Features from different embodiments may be combined to form further embodiments. For example, variations or modifications described with respect to one of the embodiments may also be applicable to other embodiments unless noted to the contrary.

The term “substantially” may be used herein to account for small manufacturing tolerances (e.g., within 5%) that are deemed acceptable in the industry without departing from the aspects of the embodiments described herein.

Gate driver circuits, digital isolators, solid state relays and isolators, isolated sensors, analog-to-digital converters, digital-to-analog converters, or other isolated devices may be used in industrial applications to communicate data between different voltage domains. Example applications include motor controls, inverters, power supplies, voltage converters, or some other application. In some embodiments, a load driving circuit comprises a high side power switch connected to a load. The high side power switch is controlled by a high side gate driver in a high voltage domain referenced to a high voltage power supply. A control signal, such as a PWM signal, for controlling the gate driver is generated in a low voltage domain. A transmitter in the low voltage domain is connected to an isolation circuit to provide galvanic isolation between the low voltage domain and the high voltage domain. A receiver is connected to the barrier circuit to receive the control signal. In some embodiments, the transmitter generates a carrier signal to communicate the control signal, and the receiver comprises one or more modulating elements to change a parameter, such as amplitude or frequency, of the carrier signal to facilitate a back channel for communicating data in the reverse direction across the isolation circuit to the transmitter.

The transition from silicon devices to wide band gap (WBG) material devices, such as silicon carbide (SiC) or gallium nitride (GaN) devices, for example, poses some challenges, as WBG switches are more sensitive to biasing conditions, and if improper biasing is done, the switches may be damaged or destroyed over time. A gate driver may have some monitoring functionality, such as UVLO (Under Voltage Lock Out), overcurrent detection, overvoltage detection, short circuit detection, overtemperature detection, or some other monitoring function. Back channel communication over the isolation circuit allows communication of bias, monitoring data, or other fault detections. In a motor control context, such conditions may be referred to as not-ready or safe torque off (STO) events.

Back channel communication may also be employed to signal fault conditions, such as detection of overcurrent or a short circuit event (DESAT or OCP) back to a host processor. The back channel communication may be signaled in a way that distinguishes a “not ready” event from a fault event.

Referring to FIG. 1 a schematic diagram of a communication device 100 is provided, according to some embodiments. In some embodiments, the communication device 100 comprises a transmitter 102 including a signal generator 102S, a barrier device 104 connected between the transmitter 102 and a receiver 106. For example, the barrier device 104 provides for galvanic isolation between the transmitter 102 and the receiver 106. Thus, transmitter 102 and receiver 106 may operate in different voltage domains. In some embodiments, the barrier device 104 may provide a voltage blocking capability of at least 650V, or at least 1200V. In the example of FIG. 1, a driver 108 is connected to the receiver 106 and is configured for controlling a power transistor 110. The power transistor 110 may be used to provide power to a connected load (not shown). In some embodiments, the transmitter 102 receives a control signal (DATA_{P}) such as a PWM signal, to control a switching state of the power transistor 110 and thereby control power provided to an attached load accordingly. The transmitter 102 may be provided in a first voltage domain, for example a low voltage domain, and transmits the control signal to the receiver 106 across the barrier device 104. In some embodiments, the power transistor 110 comprises a GaN transistor or a SiC transistor. The receiver 106 comprises one or more modulating elements 106M, such as a controllable resistance 106R, a controllable capacitance 106C or a signal generator 106S, that may be controlled to change a parameter, such as amplitude or frequency, of the carrier signal generated by the transmitter 102 to facilitate a back channel for communicating data (DATA_{BC}) from the receiver 106 in the reverse direction across the barrier device 104 to the transmitter 102.

In some embodiments, the transmitter 102 and the barrier device 104 are provided in a first semiconductor die 112, and the receiver 106 and the driver 108 are provided in a second semiconductor die 114. The first semiconductor die 112 and the second semiconductor die 114 may be provided in the same semiconductor package or in separate semiconductor packages. The barrier device 104 may be provided in the second semiconductor die 114, split between the first semiconductor die 112 and the second semiconductor die 114, or as an external circuit between the first semiconductor die 112 and the second semiconductor die 114.

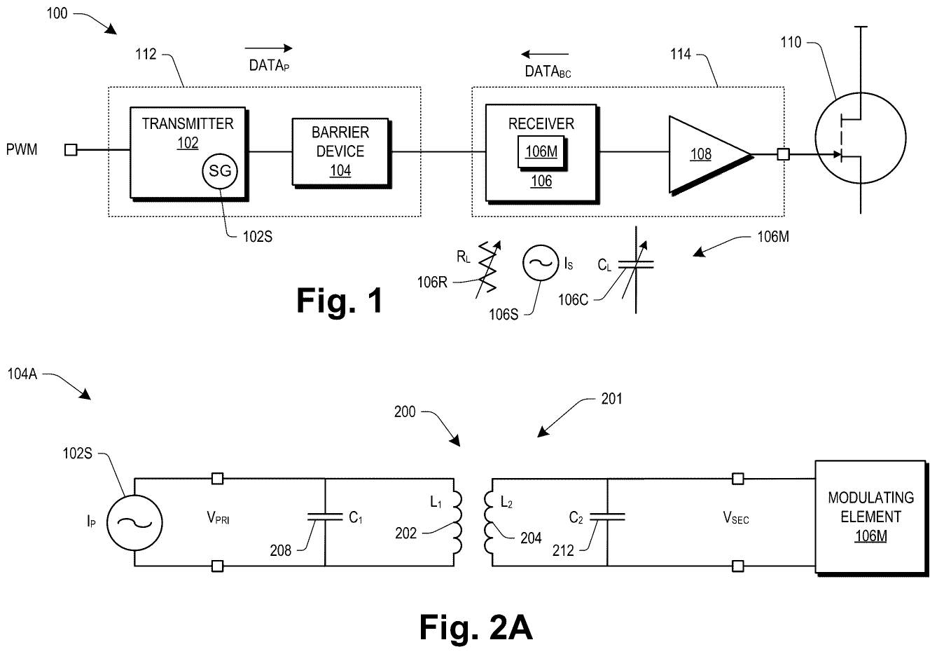

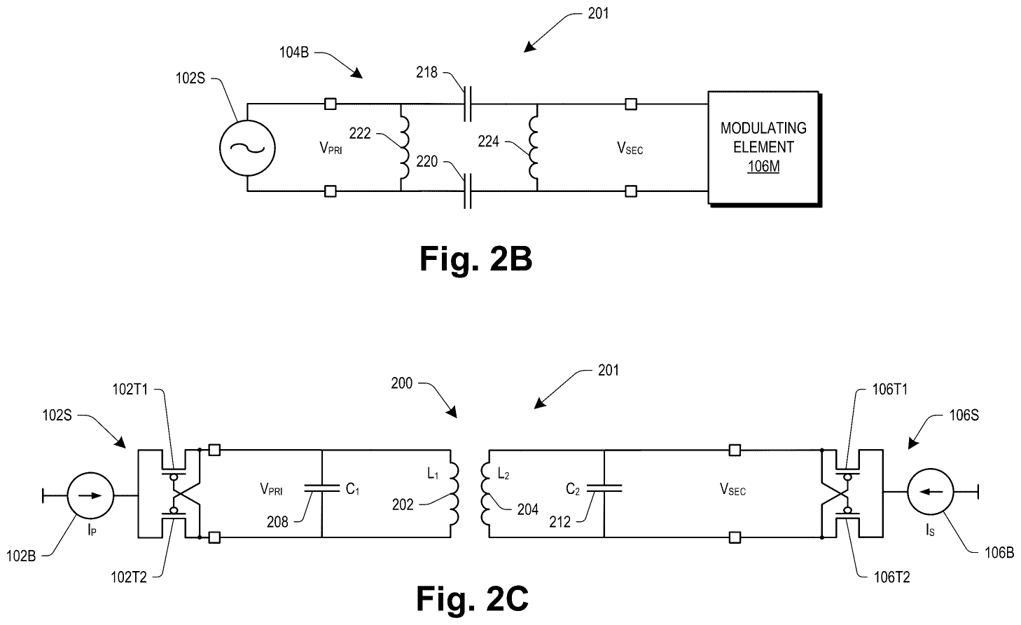

FIG. 2A is a diagram of a barrier device 104A employing inductive galvanic isolation, according to some embodiments. In some embodiments, the barrier device 104A comprises an isolation transformer 200 (i.e., an isolation barrier) including a primary winding 202 and a secondary winding 204. In some embodiments, the primary winding 202 and the secondary winding 204 may have a turn ratio of one to provide unity gain. A capacitor 208 is connected across the primary winding 202. A capacitor 212 is connected across the secondary winding 204. The capacitors 208, 212 define a tuning circuit 201. The barrier device 104A is tuned to provide a resonance condition based on a frequency of a carrier signal generated by a signal generator 102S in the transmitter 102. The signal generator 102S may be a biasing circuit that generates a carrier signal by applying a bias current to the isolation transformer 200 and the tuning circuit 201. In some embodiments, one or more modulating elements 106M are controlled to change a parameter, such as amplitude or frequency, of the carrier signal to facilitate back channel communication.

Depending on the explicit loading and tuning of the barrier device 104A, the isolation transformer 200 may operate as a traditional transformer, exhibiting two resonance frequencies, or as an impedance inverter, in a fashion similar to a quarter-wavelength transmission line, with only one resonance frequency. In the following example, the barrier device 104A is tuned to operate the isolation transformer 200 under its traditional behavior, leveraging primarily the lower frequency parallel resonance, which is used for the carrier signal to facilitate modulation for bidirectional communication.

The barrier device 104A defines two LC tanks with resonance frequencies as in equations (1) and (2) below, where ω₁ is the resonance frequency of the first LC tank, ω₂ is the resonance frequency of the second LC tank, L₁ and L₂ are the inductances of the primary winding 202 and the secondary winding 204, respectively, and C₁ and C₂ are the capacitances of the capacitors 208, 212, respectively:

$${ω}_{1} = \frac{1}{\sqrt{{L}_{1} {C}_{1}}} \qquad ( 1 )$$

$${ω}_{2} = \frac{1}{\sqrt{{L}_{2} {C}_{2}}} \qquad ( 2 )$$

The loading effect of R_{L} on the system may be quantified by the quality factor Qₛ according to equation (3), where k is the magnetic coupling factor of the transformer:

$${Q}_{s} = \frac{{R}_{L}}{\sqrt{{L}_{2} / {C}_{2}}} \frac{1}{\sqrt{1 - {k}^{2}}} . \qquad ( 3 )$$

The two parallel resonance frequencies ω_{L,H} of the system are then given by equation (4):

$${ω}_{L , H}^{2} = \frac{1 + ξ \pm \sqrt{{( 1 + ξ )}^{2} - 4 ξ ( 1 - {k}^{2} )}}{2 ( 1 - {k}^{2} )} {ω}_{2}^{2} , \qquad ( 4 )$$

with parameter

$$ξ = \frac{{ω}_{1}^{2}}{{ω}_{2}^{2}} = \frac{{L}_{2} {C}_{2}}{{L}_{1} {C}_{1}} .$$

If parameter

$$ξ = \frac{{ω}_{1}^{2}}{{ω}_{2}^{2}} = \frac{{L}_{2} {C}_{2}}{{L}_{1} {C}_{1}} = 1 ,$$

equation (4) reduces to equation (5):

$${ω}_{L , H} = \frac{{ω}_{2}}{\sqrt{1 \pm \vert k \vert}} . \qquad ( 5 )$$

If the turns ratio

$$n = \sqrt{\frac{{L}_{2}}{{L}_{1}}} = 1 ,$$

which means that, when the number of windings of the primary and secondary sides of the transformer is identical, the voltage gain of the transformer will be |Aᵥ₂₁|=|Aᵥ₁₂|=1. Thus, in this case, the resonance amplitude will be the same on both sides of the transformer.

FIG. 2B is a diagram of a barrier device 104B employing capacitive galvanic isolation, according to some embodiments. In some embodiments, the barrier device 104B comprises isolation capacitors 218, 220 (i.e., isolation barrier). Inductors 222, 224 (i.e. tuning circuit 201) are connected across the terminals of the signal generator 102S and the modulating element 106M. The barrier device 104B is tuned to provide a resonance condition based on a frequency of a carrier signal generated by a signal generator 102S in the transmitter 102 and exhibits behavior similar to the barrier device 104A of FIG. 2A. In some embodiments, the one or more modulating elements 106M are controlled to change a parameter, such as amplitude or frequency, of the carrier signal to facilitate back channel communication.

In some embodiments, the communication device 100 employs an amplitude modulation scheme where the oscillation amplitude of the carrier signal is the same on the two sides of the barrier device 104 (V_{PRI}, V_{SEC}). Multi-level amplitude modulation (i.e., Amplitude Shift Keying: ASK) can be achieved by current modulation by the transmitter 102 using the signal generator 102S and load modulation in the receiver 106 or by current modulation in both the signal generator 102S and the modulating element 106M.

In the following example, the modulation element 106M is a variable resistor 106R having a configurable resistance, R_{L}. In a current-load modulation approach, the amplitude of the oscillations follows the relation of equation (6):

$${\hat{V}}_{osc} ∝ {I}_{P} {R}_{T} , \qquad ( 6 )$$

where R_{T}=R_{eq}∥R_{L}, R_{eq} is the equivalent resistance of the barrier device 104, and I_{P} is the bias current of the signal generator 102S. The variation of I_{P} and R_{L} leads to the variation of the oscillation amplitude. Selecting I_{P} and R_{L} in discrete steps may provide discrete amplitudes of the carrier signal, which may be referred to as modulation symbols. In some embodiments, the communication device 100 employs a three-level ASK modulation to facilitate a bidirectional full duplex communication channel, wherein three symbols are defined with their amplitudes: \hat{V}ₘₐₓ, \hat{V}ᵢₙₜ and \hat{V}ₘᵢₙ. These three symbols are generated by varying I_{P} between two values (I_{Pmax} and I_{Pmin}) and by varying R_{L} between two values (Rₘₐₓ and Rₘᵢₙ). The different combination of I_{P} and Ry leads to the following scheme:
\hat{V}ₘₐₓ=I_{Pmax}Rₘₐₓ: transmitter sends ‘1’, receiver sends ‘1’,
\hat{V}ᵢₙₜ=I_{Pmin}Rₘₐₓ=I_{Pmax}Rₘᵢₙ: transmitter sends ‘1’ and receiver sends ‘0’ or transmitter sends ‘0’ and receiver sends ‘1’, and
\hat{V}ₘᵢₙ=I_{Pmin}Rₘᵢₙ: transmitter sends ‘0’, receiver sends ‘0’.

In some embodiments, the min values correspond to logic zero data values and the max values correspond to logic one data values. In other implementations, the number of levels in the ASK modulation scheme may be increased by increasing the discrete values used for I_{P} or R_{L} and the symbols may correspond to other data values.

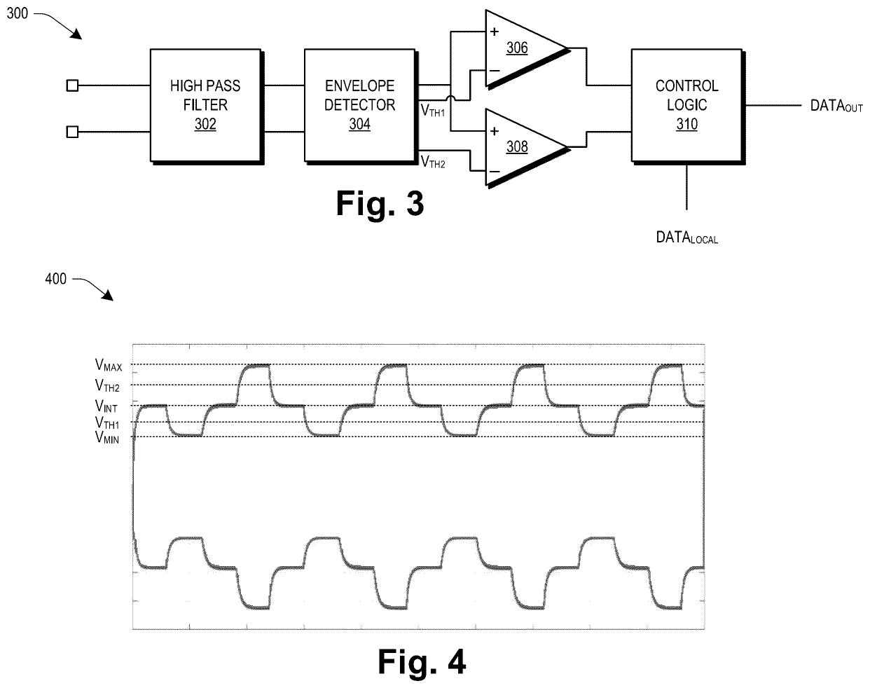

FIG. 3 is a diagram of a detector 300, according to some embodiments. The detector 300 may be used in the transmitter 102 or the receiver 106 to decode the data in the carrier signal defined by the symbols, \hat{V}ₘₐₓ, \hat{V}ᵢₙₜ and \hat{V}ₘᵢₙ. FIG. 4 is a diagram of a modulated carrier waveform 400, according to some embodiments. The detector 300 generates a metric corresponding to a parameter of the carrier signal. For example, the parameter may be an amplitude or a frequency of the carrier signal. In an embodiment, where a change in the frequency causes a corresponding change in the amplitude of the carrier signal, the detector 300 may indirectly detect the change in frequency based on the change in amplitude. In some embodiments, the detector 300 comprises a high pass filter 302 to reduce common-mode disturbances and improve common mode transient immunity (CMTI) performance, an envelope detector 304 that generates a voltage as the metric corresponding to the amplitude parameter of the carrier signal. Comparators 306, 308 determine the value of the metric using thresholds V_{TH1} and V_{TH2}, respectively, to distinguish between the three symbols, \hat{V}ₘₐₓ, \hat{V}ᵢₙₜ and \hat{V}ₘᵢₙ. The number of comparators 306, 308 corresponds to one less than the number of ASK levels (i.e., m−1 comparators for m ASK levels).

Control logic 310 decodes the data based on the outputs of the comparators 306, 308. The data sent from one side of the barrier device 104 (X) is relevant for the correct demodulation of the data coming from the other side of the barrier device 104 (Y). The control logic 310 determines the data sent from the other side based on the outputs of the comparators 306, 308 and the local data, DATA_{LOCAL}, being sent. If X and Y both send 0, X and Y both detect Vₘᵢₙ. If X and Y both send 1, X and Y both detect Vₘₐₓ. If X sends 0 to Y while Y sends 1 to X, both X and Y detect Vᵢₙₜ. X is able to decode that Y is sending a 1 since X itself knows that it is sending a 0. Similarly, Y decodes correctly a 0 from X since it knows that it is sending a 1. The logic function implemented by the control logic 310 may be defined as in equation (7):

$${B}_{RX} = \overline{{B}_{TX}} \cdot {C}_{L} + {C}_{H} , \qquad ( 7 )$$

where B_{TX} represents the transmitted data, C_{L} and C_{H} are the respective output of the comparators 306, 308 (i.e., they are high when the input of the comparator is above the threshold and low when it is below the threshold). The truth table of the logic function of equation (7) for the ASK modulation is shown in Table 1.

TABLE 1
ASK Truth Table

| | | | | Amplitude of |
|---|---|---|---|---|
| B_{TX} | C_{L} | C_{H} | B_{RX} | the oscillation |
| 0 | 0 | 0 | 0 | Vₘᵢₙ |
| 0 | 1 | 0 | 1 | Vᵢₙₜ |
| 0 | 1 | 1 | 1 | Vᵢₙₜ |
| 1 | 0 | 0 | 0 | Vᵢₙₜ |
| 1 | 1 | 0 | 0 | Vᵢₙₜ |
| 1 | 1 | 1 | 1 | Vₘₐₓ |

In some embodiments, the data values may not be 0 or 1, but rather, other data may be defined for the symbols. For example, the number of ASK levels may be increased. The states described in rows 3 and 4 may occur only as transients and may not represent stable states that are used to transmit the data.

FIG. 2C is a diagram of the barrier device 104A and signal generators 102S, 106S, according to some embodiments. In some embodiments, the signal generator 102S comprises a bias current generator 102B connected to cross-coupled transistors 102T1, 102T2, and the signal generator 106S comprises a bias current generator 106B connected to cross-coupled transistors 106T1, 106T2. On each side, the cross-coupled transistors together with the respective capacitance and windings form an oscillator circuit. The bias current generator 102B generates a bias current (I_{P}) to modulate the amplitude of the carrier signal. Similarly, the bias current generator 106B generates a bias current (I_{S}) to modulate the amplitude of the carrier signal independently from the modulation by the signal generator 102S. Using current-current modulation, the amplitude of the carrier signal is modulated by changing the bias current (I_{P}) of the signal generator 102S in the transmitter 102 and the bias current (I_{S}) of the signal generator 106S. The oscillation amplitude of the carrier signal on the two sides of the barrier device 104 is given in equations (8) and (9) below:

$${V}_{PRI} = {α}_{P} {I}_{P} + {α}_{S} {I}_{S} , \qquad ( 8 )$$

$${V}_{SEC} = {β}_{P} {I}_{P} + {β}_{S} {I}_{S} , \qquad ( 9 )$$

where α_{P}, α_{S}, β_{P}, β_{S} are arbitrary scaling factors that allow definition of the oscillation amplitudes for the modulation symbols. To achieve three-level ASK modulation, maximum and minimum values are defined for I_{P} and I_{S} to generate the symbols illustrated in the waveform 400 in FIG. 4. Additional ASK levels may be defined using intermediate bias levels, thereby supporting symbol definitions corresponding to data values in addition to or different than logic 1 and logic 0. The bias current based signal generator 102S illustrated in FIG. 2C may be employed in any of the other embodiments described herein.

In some embodiments, the transmitter 102 employs on-off keying (OOK) modulation where the carrier signal is present (e.g., a periodic signal such as a square wave) during time intervals that the PWM signal is active and off during time intervals that the PWM signal is inactive. In some embodiments, since the carrier signal is not present during off periods of the OOK signal, back channel communication by the receiver 106 is conducted only during on periods to communicate UVLO or fault events.

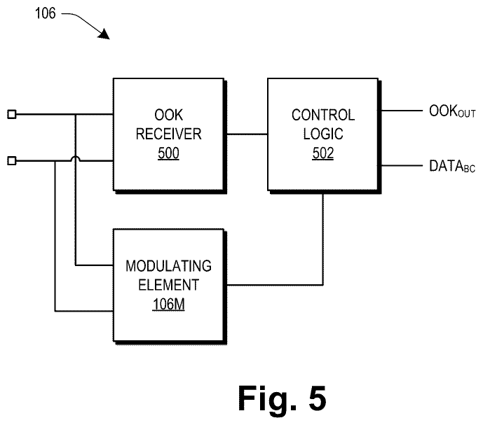

FIG. 5 is a diagram of the receiver 106 configured for OOK communication, according to some embodiments. In some embodiments, the receiver 106 comprises an OOK receiver 500 that detects on and off intervals of the carrier signal, for example using envelope detection, and control logic 502 that extracts the OOK_{OUT} data and controls the modulating element 106M to encode back channel data, DATA_{BC}.

In some embodiments, the modulating element 106M comprises a variable capacitor 106C to facilitate frequency or amplitude modulation for back channel communication. For frequency modulation, C_{L} is changed to shift the tuning of the barrier device 104 to shift from locking on to the lower parallel resonance frequency to locking on to the higher parallel resonance frequency (i.e., or vice versa). The change in resonance frequency causes a change in amplitude that may be detected by the comparators 306, 308 in FIG. 3. Regarding a capacitive load frequency modulation solution, the parallel resonance frequencies are given by equation (4) above.

Depending on the value of k and ξ the signal generator 102S will lock on to ω_{L} or ω_{H}, where ξ will change dependant on C_{L} (in this case, (C₂+C_{L}) are to be used in the formula at the location of C₂). Discrete steps of C_{L} will result in discrete frequency steps that correspond to modulation symbols. The number of different C_{L} (m) sets the number of symbols that can be transmitted on the back channel.

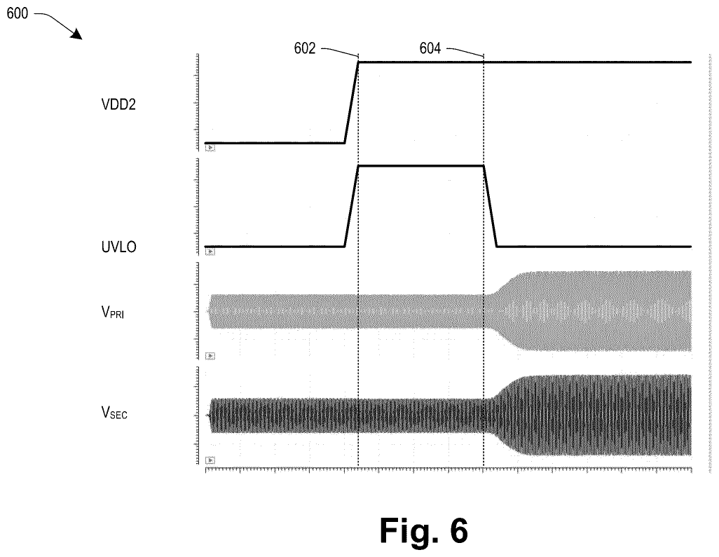

FIGS. 6-8 are diagrams of modulated carrier waveforms 600, 700, 800 used for communication, according to some embodiments. In the example of FIG. 6, the transmitter 102 asserts the on cycle of the OOK carrier signal at time zero, however, the receiver 106 is in a shutdown state (low level for VDD2). In the shutdown state, the receiver 106 configures the modulating element 106M to reduce the amplitude of the carrier signal. For example, if the modulating element 106M is a variable resistor 106R, a low resistance may be selected, and if the modulating element 106M is a signal generator 106S, a low (or zero) bias level may be selected. The receiver 106 starts up at 602 and asserts an UVLO signal and configures the modulating element 106M to reduce the amplitude of the carrier signal. The transmitter 102 decodes the UVLO condition based on the detected amplitude of the carrier signal. In this example, only one comparator 306, 306 is required in the detector 300. After the UVLO signal in the receiver 106 clears at 604, the receiver 106 changes the state of the modulating element 106M to indicate the UVLO being cleared. For example, if the modulating element 106M is a variable resistor 106R, a high resistance may be selected, and if the modulating element 106M is a signal generator 106S, a high bias level may be selected.

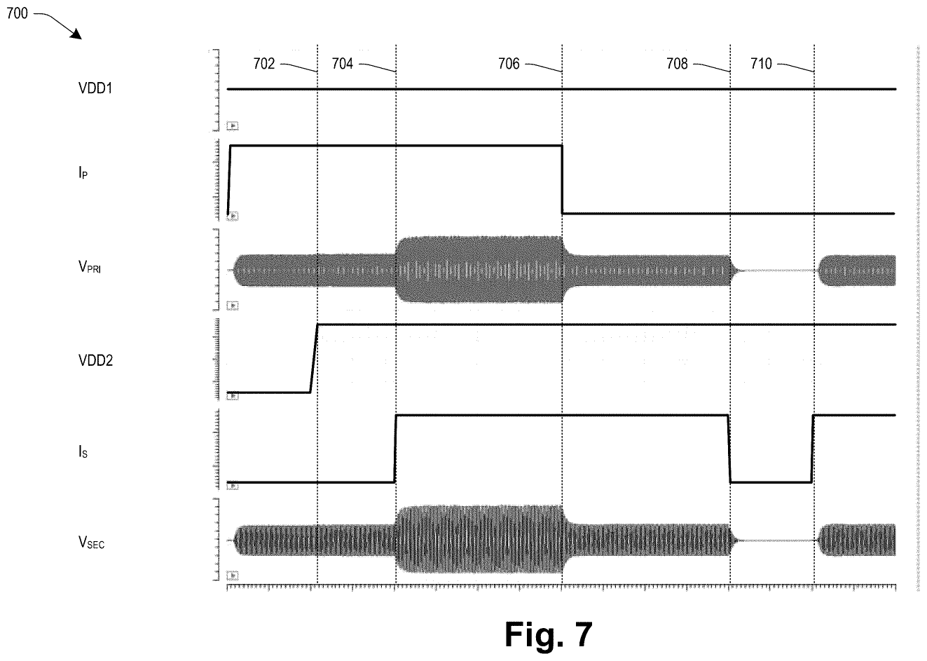

In the example of FIG. 7, the modulating element 106M comprises a signal generator 106S. Active amplitude modulation is conducted by the receiver 106 to communicate back channel data. VDD2 is the power supply of the receiver 106, I_{S} is the bias signal of the signal generator 106S in the receiver 106, and I_{P} is the bias signal of the signal generator 102S in the transmitter 102. The transmitter 102 starts the OOK high at time 0 with I_{P} high. The receiver 106 starts up at 702. The receiver 106 sets Is high at 704 and the amplitude of the carrier signal increases. At 706, the transmitter 102 sets I_{P} low, reducing the amplitude of the carrier signal. When both I_{P} and I_{S} are low at 708 there is no carrier signal. The receiver 106 can generate the carrier signal independent of the transmitter 102 at 710 by setting I_{S} high when I_{P} is off. These various ASK states can be used to communicate symbols in either direction. The transmitter 102 can decode data from the receiver 106 because the transmitter 102 knows its own modulation state. Similarly, the receiver 106 can decode data from the transmitter 102 because the receiver 106 knows its own modulation state.

In some embodiments, passive and active modulation can be mixed by providing multiple modulation elements 106M. For example, a variable resistor 106R or a variable capacitor 106C may be used for passive modulation for UVLO or not-ready and a signal generator 106S may be used for active modulation for fault communication.

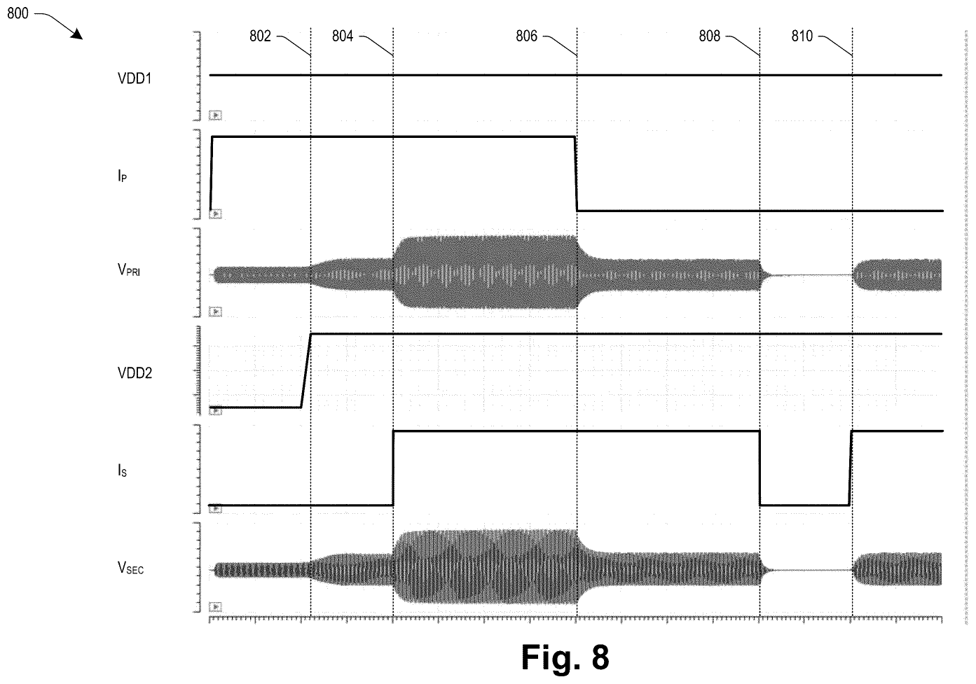

In the example of FIG. 8, the modulating element 106M comprises a signal generator 106S and a passive element such as a variable resistor 106R or a variable capacitor 106C. Active and passive amplitude modulation are conducted by the receiver 106 to communicate back channel data. VDD2 is the power supply of the receiver 106, I_{S} is the bias signal of the signal generator 106S in the receiver 106, and I_{P} is the bias signal of the signal generator 102S in the transmitter 102. The transmitter 102 starts the OOK high at time 0 with I_{P} high. The receiver 106 provides passive clamping at time zero when VDD2 is low by setting the passive modulating element 106R, 106C to increase the load. The receiver 106 starts up at 802, and the passive modulating element 106R, 106C is set to decrease the load and increase the amplitude of the carrier signal. This scheme communicates to the transmitter 102 that the receiver 106 is ready. The receiver 106 sets I_{S} high at 804 and the amplitude of the carrier signal increases. At 806, the transmitter 102 sets I_{P} low, reducing the amplitude of the carrier signal. When both I_{P} and I_{S} are low at 808 there is no carrier signal. The receiver 106 can generate the carrier signal independent of the transmitter 102 at 810 by setting I_{S} high when I_{P} is off. These various ASK states can be used to communicate symbols in either direction. The transmitter 102 can decode data from the receiver 106 because the transmitter 102 knows its own modulation state. Similarly, the receiver 106 can decode data from the transmitter 102 because the receiver 106 knows its own modulation state.

In some embodiments, the modulating element 106M may be one or more of a passive modulating element or an active modulating element. Other types of modulating elements include active clamp circuits, other types of active circuits that modulate a parameter of the carrier signal, or other types of passive load circuits that modulate a parameter of the carrier signal.

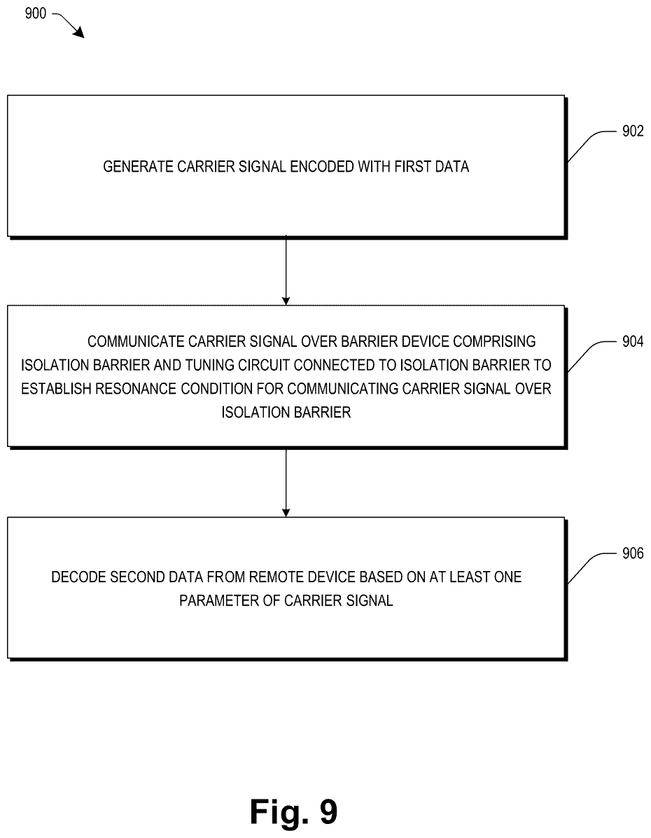

FIG. 9 illustrates a method 900 of communicating data, in accordance with some embodiments. At 902 a carrier signal encoded with first data is generated. At 904, the carrier signal is communicated over a barrier device 104, comprising an isolation barrier 200, 218, 220 and a tuning circuit 201 connected to the isolation barrier 200, 218, 220 to establish a resonance condition for communicating the carrier signal over the isolation barrier 200, 218, 220. At 906, second data from a remote device (e.g. the receiver 106) is decoded based on at least one parameter of the carrier signal.

In some embodiments, the carrier signal may be generated and communicated over the isolation barrier at a non-resonant frequency. For example, the signal generator generates the carrier signal at a frequency that does not correspond to a resonance frequency of the barrier device. In this case, the tuning circuit connected to the isolation barrier may be configured to establish a steady-state condition. In other words, the tuning circuit may be configured to establish a predefined oscillation behavior of the barrier device without necessarily establishing a resonance condition based on the carrier signal. In some embodiments, the tuning circuit may be configured to establish the steady-state condition such that a resonance frequency of the barrier device is different than a frequency of the carrier signal.

Thus, the tuning circuit connected to the isolation barrier may be configured to tune the oscillation behavior and/or the impedance of the barrier device such that the carrier signal can be communicated over the isolation barrier without relying on resonance. Here, the circuit may operate in a forced oscillation mode. Such operation mode may require more power and/or a signal-to-noise ratio of the transmitted signal may be lower than in the resonant case, but other parameters of the communication device may be improved, such as EMI compatibility. In some embodiments, the tuning circuit may be configured to tune the barrier device such that an amplitude of the carrier signal is larger than a predefined lower threshold and smaller than a predefined upper threshold. Here, the lower threshold may be larger than 0 and the upper threshold may be less than 50%, or less than 20%, of a corresponding amplitude at resonance. “Corresponding amplitude at resonance” may refer to the amplitude that would be achieved at the same conditions (i.e., drive strength, load conditions, etc.) but at resonance frequency. In further embodiments, the tuning circuit may be configured to tune the barrier device such that a return loss of the carrier signal is higher than at the resonance condition.

According to some embodiments, a communication device comprises a signal generator configured to generate a carrier signal, control logic configured to encode first data in the carrier signal, a barrier device comprising an isolation barrier connected to the signal generator and a tuning circuit connected to the isolation barrier to establish a resonance condition for communicating the carrier signal over the isolation barrier, and a receiver configured to decode second data from a remote device based on at least one parameter of the carrier signal.

According to some embodiments, the remote device is configured to modify the at least one parameter of the carrier signal to encode the second data and the remote device is configured to decode the first data based on the carrier signal.

According to some embodiments, the control logic is configured to modify the at least one parameter of the carrier signal to encode the first data, the remote device is configured to decode the first data based on the second data and the at least one parameter of the carrier signal, and the receiver is configured to decode the second data based on the at least one parameter of the carrier signal and the first data.

According to some embodiments, the at least one parameter of the carrier signal has a first value responsive to the first data comprising a first data value and the second data comprising the first data value, a second value responsive to one of the first data or the second data comprising the first data value and the other of the first data or the second data comprising a second data value, and a third value responsive to the first data and the second data comprising the second data value.

According to some embodiments, the at least one parameter of the carrier signal comprises a first parameter that has a first value responsive to a first combination of the first data and the second data, a second parameter that has a second value responsive to a second combination of the first data and the second data, and a third parameter has a third value responsive to a third combination of the first data and the second data.

According to some embodiments, at least one of the first parameter, the second parameter, or the third parameter comprises an amplitude parameter, and at least one of the first parameter, the second parameter, or the third parameter comprises a frequency parameter.

According to some embodiments, the receiver comprises a detector configured to generate a metric corresponding to the at least one parameter of the carrier signal, generate a first detection flag responsive to the metric meeting a first threshold, and generate a second detection flag responsive to the metric meeting a second threshold and the control logic is configured to decode the second data as a first data value responsive to the first detection flag not being asserted, decode the second data as a second data value responsive to the first detection flag being asserted and the first data comprising the first data value, decode the second data as the second data value responsive to the second detection flag being asserted, and decode the second data as the first data value responsive to the first detection flag being asserted and the first data comprising the second data value.

According to some embodiments, the remote device comprises a detector configured to generate a metric corresponding to the at least one parameter of the carrier signal, generate a first detection flag responsive to the metric meeting a first threshold, and generate a second detection flag responsive to the metric meeting a second threshold, and second control logic configured to decode the first data as a first data value responsive to the first detection flag not being asserted, decode the first data as a second data value responsive to the first detection flag being asserted and the second data comprising the first data value, decode the first data as the second data value responsive to the second detection flag being asserted, and decode the first data as the first data value responsive to the first detection flag being asserted and the second data comprising the second data value.

According to some embodiments, the detector comprises a first comparator configured to generate the first detection flag responsive to the metric being greater than the first threshold and a second comparator configured to generate the second detection flag responsive to the metric being greater than the second threshold.

According to some embodiments, the remote device comprises a second signal generator, a modulating element, and second control logic configured to control a bias level of the second signal generator to modify the at least one parameter of the carrier signal to encode the second data and to control the modulating element to modify the at least one parameter of the carrier signal to encode third data.

According to some embodiments, the remote device comprises at least one of a variable resistor, a variable reactive element, or a current modulator configured to modify the at least one parameter of the carrier signal to encode the second data and second control logic configured to control the at least one of the variable resistor, the variable reactive element, or the current modulator based on the second data.

According to some embodiments, the control logic is configured to control the signal generator to encode the first data using on-off keying modulation of the carrier signal and the receiver is configured to decode the second data during on periods of the on-off keying modulation of the carrier signal.

According to some embodiments, the at least one parameter comprises at least one of amplitude or frequency.

According to some embodiments, the receiver comprises an envelope detector configured to generate a metric corresponding to the at least one parameter of the carrier signal and a comparator configured to generate a detection flag responsive to the metric meeting a threshold, and the control logic is configured to decode the second data as a first data value responsive to the detection flag not being asserted and decode the second data as a second data value responsive to the detection flag being asserted.

According to some embodiments, a gate driver comprises an on-off keying receiver configured to decode first data from a carrier signal, a device configured to modify at least one parameter of the carrier signal, and control logic configured to control the device to encode second data.

According to some embodiments, the at least one parameter of the carrier signal has a first value responsive to the second data comprising a first data value and a second value responsive to the second data comprising a second data value.

According to some embodiments, the device comprises a signal generator and the control logic is configured to control a bias level of the signal generator to modify the at least one parameter of the carrier signal to encode the second data.

According to some embodiments, the gate driver comprises a modulating element, wherein the control logic is configured to control the modulating element to modify the at least one parameter of the carrier signal to encode third data.

According to some embodiments, the device comprises at least one of a variable resistor, a variable reactive element, or a current modulator configured to modify the at least one parameter of the carrier signal and the control logic is configured to control the at least one of the variable resistor, the variable reactive element, or the current modulator based on the second data.

According to some embodiments, the at least one parameter comprises at least one of amplitude or frequency.

According to some embodiments, a method comprises generating a carrier signal encoded with first data, communicating the carrier signal over a barrier device, the barrier device comprising an isolation barrier and a tuning circuit connected to the isolation barrier to establish a resonance condition for communicating the carrier signal over the isolation barrier, and decoding second data from a remote device based on at least one parameter of the carrier signal.

According to some embodiments, the method comprises modulating the at least one parameter of the carrier signal in a device connected to the barrier device to encode the second data and decoding the first data based on the carrier signal in the device.

According to some embodiments, decoding the first data comprises decoding the first data based on the at least one parameter of the carrier signal and the second data and decoding second data comprises decoding the second data based on the at least one parameter of the carrier signal and the first data.

According to some embodiments, decoding second data comprises decoding the second data during on periods of an on-off keying of the carrier signal.

According to some embodiments, decoding the second data comprises generating a metric corresponding to the at least one parameter of the carrier signal, generating a first detection flag responsive to the metric meeting a first threshold, generating a second detection flag responsive to the metric meeting a second threshold, decoding the second data as a first data value responsive to the first detection flag not being asserted, decoding the second data as a second data value responsive to the first detection flag being asserted and the first data comprising the first data value, decoding the second data as the second data value responsive to the second detection flag being asserted, and decoding the second data as the first data value responsive to the first detection flag being asserted and the first data comprising the second data value.

According to some embodiments, the at least one parameter comprises at least one of amplitude or frequency.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Moreover, “exemplary” and/or the like is used herein to mean serving as an example, instance, illustration, etc., and not necessarily as advantageous. Rather, use of the word “example” and/or the like is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

1. A communication device, comprising:
a signal generator configured to generate a carrier signal;
control logic configured to encode first data in the carrier signal;
a barrier device, comprising:
an isolation barrier connected to the signal generator; and
a tuning circuit connected to the isolation barrier to establish a resonance condition for communicating the carrier signal over the isolation barrier; and
a receiver configured to decode second data from a remote device based on at least one parameter of the carrier signal.

2. The communication device of claim 1, wherein:
the remote device is configured to modify the at least one parameter of the carrier signal to encode the second data; and
the remote device is configured to decode the first data based on the carrier signal.

3. The communication device of claim 2, wherein:
the control logic is configured to modify the at least one parameter of the carrier signal to encode the first data;
the remote device is configured to decode the first data based on the second data and the at least one parameter of the carrier signal; and
the receiver is configured to decode the second data based on the at least one parameter of the carrier signal and the first data.

4. The communication device of claim 1, wherein:
the at least one parameter of the carrier signal has:
a first value responsive to the first data comprising a first data value and the second data comprising the first data value,
a second value responsive to one of the first data or the second data comprising the first data value and the other of the first data or the second data comprising a second data value, and
a third value responsive to the first data comprising the second data value and the second data comprising the second data value.

5. The communication device of claim 1, wherein:
the at least one parameter of the carrier signal comprises:
a first parameter that has a first value responsive to a first combination of the first data and the second data,
a second parameter that has a second value responsive to a second combination of the first data and the second data, and
a third parameter has a third value responsive to a third combination of the first data and the second data.

6. The communication device of claim 1, wherein:
the receiver comprises:
a detector configured to:
generate a metric corresponding to the at least one parameter of the carrier signal;
generate a first detection flag responsive to the metric meeting a first threshold; and
generate a second detection flag responsive to the metric meeting a second threshold; and
the control logic is configured to:
decode the second data as a first data value responsive to the first detection flag not being asserted;
decode the second data as a second data value responsive to the first detection flag being asserted and the first data comprising the first data value;
decode the second data as the second data value responsive to the second detection flag being asserted; and
decode the second data as the first data value responsive to the first detection flag being asserted and the first data comprising the second data value.

7. The communication device of claim 6, wherein:
the detector comprises:
a first comparator configured to generate the first detection flag responsive to the metric being greater than the first threshold; and
a second comparator configured to generate the second detection flag responsive to the metric being greater than the second threshold.

8. The communication device of claim 2, wherein:
the remote device comprises:
a detector configured to:
generate a metric corresponding to the at least one parameter of the carrier signal;
generate a first detection flag responsive to the metric meeting a first threshold; and
generate a second detection flag responsive to the metric meeting a second threshold; and
second control logic configured to:
decode the first data as a first data value responsive to the first detection flag not being asserted;
decode the first data as a second data value responsive to the first detection flag being asserted and the second data comprising the first data value;
decode the first data as the second data value responsive to the second detection flag being asserted; and
decode the first data as the first data value responsive to the first detection flag being asserted and the second data comprising the second data value.

9. The communication device of claim 2, wherein:
the remote device comprises:
a second signal generator;
a modulating element; and
second control logic configured to control a bias level of the second signal generator to modify the at least one parameter of the carrier signal to encode the second data and to control the modulating element to modify the at least one parameter of the carrier signal to encode third data.

10. The communication device of claim 2, wherein:
the remote device comprises:
at least one of a variable resistor, a variable reactive element, or a current modulator configured to modify the at least one parameter of the carrier signal to encode the second data; and
second control logic configured to control the at least one of the variable resistor, the variable reactive element, or the current modulator based on the second data.

11. The communication device of claim 1, wherein:
the control logic is configured to control the signal generator to encode the first data using on-off keying modulation of the carrier signal; and
the receiver is configured to decode the second data during on periods of the on-off keying modulation of the carrier signal.

12. The communication device of claim 1, wherein:
the receiver comprises:
an envelope detector configured to generate a metric corresponding to the at least one parameter of the carrier signal; and
a comparator configured to generate a detection flag responsive to the metric meeting a threshold; and
the control logic is configured to:
decode the second data as a first data value responsive to the detection flag not being asserted; and
decode the second data as a second data value responsive to the detection flag being asserted.

13. A gate driver, comprising:
an on-off keying receiver configured to decode first data from a carrier signal;
a device configured to modify at least one parameter of the carrier signal; and
control logic configured to control the device to encode second data.

14. The gate driver of claim 13, wherein:
the at least one parameter of the carrier signal has a first value responsive to the second data comprising a first data value and a second value responsive to the second data comprising a second data value.

15. The gate driver of claim 13, wherein:
the device comprises a signal generator; and
the control logic is configured to control a bias level of the signal generator to modify the at least one parameter of the carrier signal to encode the second data.

16. The gate driver of claim 13, comprising:
a modulating element, wherein:
the control logic is configured to control the modulating element to modify the at least one parameter of the carrier signal to encode third data.

17. The gate driver of claim 13, wherein:
the device comprises:
at least one of a variable resistor, a variable reactive element, or a current modulator configured to modify the at least one parameter of the carrier signal; and
the control logic is configured to control the at least one of the variable resistor, the variable reactive element, or the current modulator based on the second data.

18. A method, comprising:
generating a carrier signal encoded with first data;
communicating the carrier signal over a barrier device, the barrier device comprising:
an isolation barrier; and
a tuning circuit connected to the isolation barrier to establish a resonance condition for communicating the carrier signal over the isolation barrier; and
decoding second data from a remote device based on at least one parameter of the carrier signal.

19. The method of claim 18, comprising:
modulating the at least one parameter of the carrier signal in a device connected to the barrier device to encode the second data; and
decoding the first data based on the carrier signal in the device.

20. The method of claim 19, wherein:
decoding the first data comprises decoding the first data based on the at least one parameter of the carrier signal and the second data; and
decoding second data comprises decoding the second data based on the at least one parameter of the carrier signal and the first data.
